(19) United States
(12) Patent Application Publication
(10) Pub. No.: US 2007/0153457 A1
(43) Pub. Date: Jul. 5, 2007

(54) PORTABLE ELECTRONIC DEVICE

(75) Inventors: Toshiaki HOSOYA, Chiba-ken (JP); Tetsuya IWAKAMI, Kanagawa-ken (JP); Hidenori SAITO, Fukuoka-ken (JP)

Correspondence Address: BANNER & WITCOFF, LTD.;ATTORNEYS FOR CLIENT NO. 000449, 001701, 1100 13th STREET, N.W., SUITE 1200, WASHINGTON, DC, 20005-4051, US

(73) Assignee: KABUSHIKI KAISHA TOSHIBA, Tokyo (JP)

(21) Appl. No.: 11/613,575

(22) Filed: Dec. 20, 2006

(30) Foreign Application Priority Data
Jan. 4, 2006 (JP) 2006-000053

(51) Int. Cl. G06F 1/16; H05K 5/00; H05K 7/00

(52) U.S. Cl. 361/681

(57) ABSTRACT

A portable electronic device includes: an operating section; a display section configured to perform display based on information transmitted from the operating section; a light emitting element provided in one of the operating section and the display section; and a light receiving element provided in other of the operating section and the display section. The operating section and the display section are enabled to be in an open state and a closed state by changing a superposition condition thereof. An optical path interconnecting the light emitting element and the light receiving element in the open state is different from an optical path interconnecting the light emitting element and the light receiving element in the closed state.

### CROSS-REFERENCE TO RELATED APPLICATIONS

This application is based upon and claims the benefit of priority from the prior Japanese Patent Application No. 2006-000053, filed on Jan. 4, 2006; the entire contents of which are incorporated herein by reference.

### BACKGROUND

A portable electronic device such as a mobile phone, notebook personal computer, and PDA (Personal Digital Assistant) is composed of an operating section and a display section, which are often superposed on each other in a folding, rotating, or sliding design. Any of these designs requires signals to be correctly transmitted and received between the display section and the operating section. In folding and sliding designs, flexible substrates (or flexible cables) or the like have been used for maintaining electrical connection.

With the enhancement of communication features such as full-color video transmission, the amount of data transmission is increased, which requires a wider transmission bandwidth up to 400 MHz, for example. Such high-speed transmission involves susceptibility to external noise, which increases malfunctions as well. One method of solving these problems is to use optical fiber transmission. However, in optical fiber transmission, movable portions similar to the flexible substrate in electrical connection decrease reliability of transmission paths due to their wear and breaking.

Instead of optical fibers having movable portions, a technology for using free-space optical transmission has been disclosed (US 2003/0087610 A1). However, in this publication, an infrared communication unit must be housed inside a connecting portion, which significantly constrains the device design and the device assembly process. Moreover, while the technology is applicable to a rotating structure in which the connecting portion is composed of a hinge portion, it is not suitable to sliding structures.

### SUMMARY

According to an aspect of the invention, there is provided a portable electronic device including: an operating section; a display section configured to perform display based on information transmitted from the operating section; a light emitting element provided in one of the operating section and the display section; and a light receiving element provided in other of the operating section and the display section, the operating section and the display section being enabled to be in an open state and a closed state by changing a superposition condition thereof, and an optical path interconnecting the light emitting element and the light receiving element in the open state being different from an optical path interconnecting the light emitting element and the light receiving element in the closed state.

According to an aspect of the invention, there is provided a portable electronic device including: an operating section; a display section configured to perform display based on information transmitted from the operating section; a first light emitting element provided in one of the operating section and the display section; and a first light receiving element provided in other of the operating section and the display section, the operating section and the display section being enabled to be in an open state and a closed state by changing a superposition condition thereof, a first optical path interconnecting the first light emitting element and the first light receiving element in the open state being different from a second optical path interconnecting the first light emitting element and the first light receiving element in the closed state, and a first optical guide being provided in at least a part of the first optical path and in at least a part of the second optical path.

According to an aspect of the invention, there is provided a portable electronic device including: an operating section; a display section configured to perform display based on information transmitted from the operating section; a first light emitting element provided in one of the operating section and the display section; and a first light receiving element provided in other of the operating section and the display section, the operating section and the display section being enabled to be in an open state and a closed state by changing a superposition condition thereof, at least one of the operating section and the display section being provided with a space for propagating light emitted from the light emitting element, and different optical paths being formed in the open state and in the closed state by a reflecting plate provided in at least one of the operating section and the display section.

### BRIEF DESCRIPTION OF THE DRAWINGS

FIG. 1 is a cross section showing a folding mobile phone in a first example;

FIG. 2 is a view showing the optical path in the molded transparent resin portion;

FIG. 3 is a cross section showing a sliding mobile phone in a second example;

FIG. 4 is a cross section showing a rotating mobile phone in a third example;

FIG. 5 is a plan view of the rotating mobile phone in the third example;

FIG. 6 is a plan view of a mobile phone in a fourth example;

FIG. 7 is a cross section of a sliding mobile phone in a fifth example;

FIG. 8 is a cross section showing a variation of the fifth example;

FIG. 9A is a partial plan view in the vicinity of a hinge portion of a folding mobile phone in a sixth example, and

FIG. 9B is a partial cross section thereof;

FIG. 10 shows an operating section optical element mounting substrate of the folding mobile phone in the sixth example;

FIG. 11 shows an operating section optical element mounting substrate of the folding mobile phone in a first variation of the sixth example;

FIG. 12A is a view of a notebook personal computer in a second variation of the sixth example, and

FIG. 12B is a partial cross section in the vicinity of a hinge portion thereof;

FIG. 13A is a partial plan view of a rotating mobile phone in a third variation of the sixth example, and

FIG. 13B is a partial cross section thereof;

FIG. 14 shows an electronic device in its closed state in a fourth variation of the sixth example, where

FIG. 14A is a view of an operating section optical element mounting substrate,

FIG. 14B is a view of a display section optical element mounting substrate, and

FIG. 14C is a side view in the vicinity of a hinge portion;

FIG. 15 shows the electronic device in its intermediate position between the closed and open states in the fourth variation of the sixth example, where

FIG. 15A is a view of the operating section optical element mounting substrate,

FIG. 15B is a view of the display section optical element mounting substrate, and

FIG. 15C is a side view in the vicinity of the hinge portion;

FIG. 16 shows the electronic device in its intermediate position between the closed and open states in the fourth variation of the sixth example, where

FIG. 16A is a view of the operating section optical element mounting substrate,

FIG. 16B is a view of the display section optical element mounting substrate, and

FIG. 16C is a side view in the vicinity of the hinge portion; and

FIG. 17 shows the electronic device in its open state in the fourth variation of the sixth example, where

FIG. 17A is a view of the operating section optical element mounting substrate,

FIG. 17B is a view of the display section optical element mounting substrate, and

FIG. 17C is a side view in the vicinity of the hinge portion.

### DETAILED DESCRIPTION

Embodiments of the invention will now be described with reference to the drawings.

### FIRST EXAMPLE

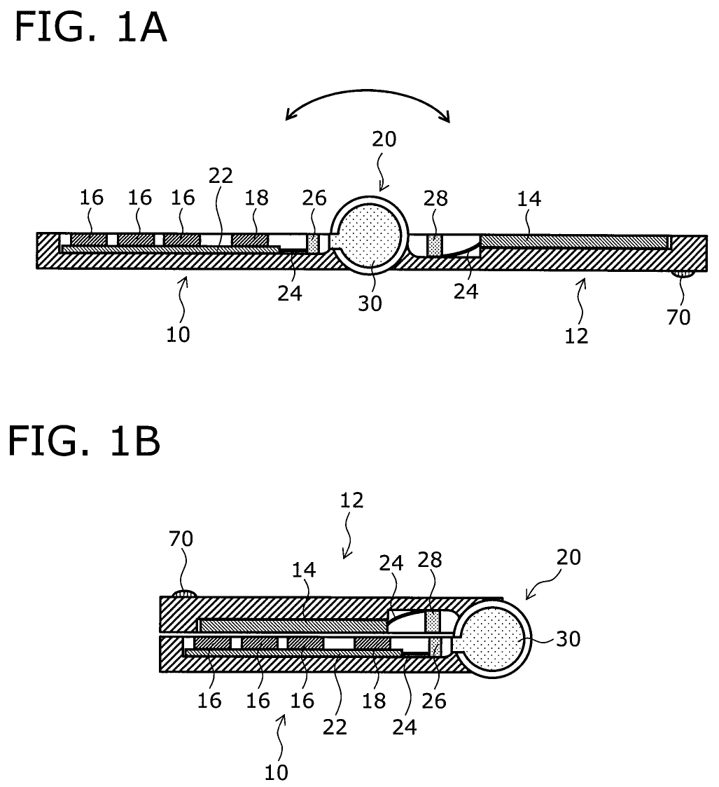

FIG. 1A is a cross section showing a folding mobile phone in its open state in a first example, and FIG. 1B is a cross section showing the mobile phone of this example in its closed state. This mobile phone has a structure in which two housings are superposed on each other. One of the housings, an operating section 10, and the other, a display section 12, are connected via a hinge portion 20, and can be opened and closed by rotating around the central axis of the hinge portion 20 in foldable manner.

In the open state, the operating section 10 and the display section 12 are maximally opened as illustrated in FIG. 1A. In the closed state, the operating section 10 and the display section 12 are substantially superposed on each other as shown in FIG. 1B. While they are superposed in a folding design in this example, sliding and rotating designs can also be used as described later.

The operating section 10 includes a control substrate 22 fixed in its housing and having thereon a transceiver, a memory element, a control circuit, key switches 16, and a power switch 18. The operating section 10 further includes a light emitting element 26 for free-space optical communication with the display section 12 and a connecting line 24 for electrically connecting the control substrate 22 to the light emitting element 26.

The display section 12 includes a liquid crystal display 14 for displaying the transmitting/receiving state and email content, a light receiving element 28 for receiving data from the operating section 10, a connecting line 24 for electrically connecting the liquid crystal display 14 to the light receiving element, and a camera section 70. The display may be an organic EL display, for example.

The light emitting element 26 for transmitting data from the operating section 10 to the display section 12 by free-space optical transmission can be an LED (Light Emitting Diode) or VCSEL (Vertical Cavity Surface Emitting Laser). An optical signal from the light emitting element 26 is introduced into an optical guide 30 which may be a molded transparent resin provided in the vicinity of the hinge portion 20. Part of the light introduced into the molded transparent resin portion (optical guide) 30, which illustratively has a generally circular cross section adapted to the shape of the hinge portion 20, propagates with repeated reflections at the interface with the exterior (air). The light is then incident on the light receiving element 28 in the display section 12. In this way, the data from the operating section 10 is transmitted to the display section 12.

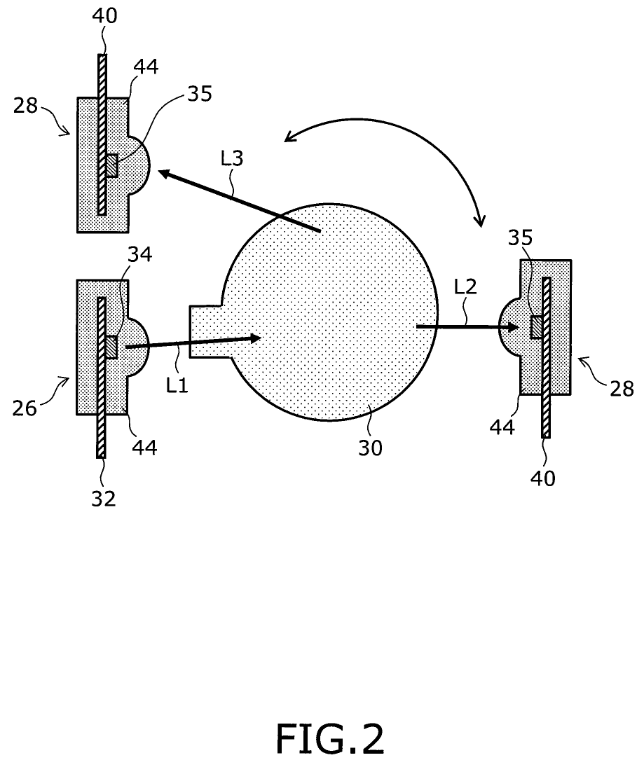

Here the optical path inside the molded transparent resin portion 30 is described. FIG. 2 is a view showing the optical path. An LED chip 34 is mounted on a lead 32 and sealed with a mold resin 44, thereby configuring the light emitting element 26. Furthermore, a photodiode chip 35 is mounted on a lead 40 and sealed with a mold resin 44, thereby configuring the light receiving element 28.

As illustrated in FIG. 2, if the surface of the molded transparent resin portion 30 facing to the light emitting element 26 is made generally perpendicular to the central axis of the light emitting element 26, the incident light L1 spreads entirely in the molded transparent resin portion 30. The incident light can be further spread by using a light emitting element 26, which has a large orientation angle. The light can then propagate in the molded transparent resin portion 30 by repeating total reflection at the interface with exterior.

However, the light receiving element 28 changes its position between the open state illustrated in FIG. 1A and the closed state illustrated in FIG. 1B. In the open state, the transmitted light L2 from the molded transparent resin portion 30 is incident on the light receiving element 28. Even after rotation, the light L3 emitted after propagating in the molded transparent resin 30 by reflection is incident on the light receiving element 28. In this way, light can be transmitted at a position between the open state and the closed state.

One of the features of this example is that the optical path differs between the open state and the closed state. This substantially prevents durability issues such as mechanical wear due to motion of flexible substrates (or flexible cables) at each time of folding. Such an optical path can exploit the space in the housings and thus increases the flexibility of arrangement of parts on the control substrate 22 in the housing.

Advantages of using optical transmission are now described. Full-color video display is increasingly demanded in mobile phones and PDAs. This requires a transmission bandwidth as wide as about 400 MHz. To achieve this with an electrical cable, at least ten cables are needed. It is difficult for a portable device limited in size to enclose such many electrical cables and flexible substrates. Free-space optical transmission can overcome these problems.

Moreover, optical transmission can also reduce the effect of external noise. For example, free-space optical transmission can prevent potential deterioration of the bit error rate of a mobile phone due to external noise. Free-space optical transmission can also prevent the effect of external noise on the control signal which may result in malfunctions of the device and disturbances of the image on the liquid crystal display 14. Free-space optical transmission can prevent adverse effects on other electronics due to external emission of noise from long flexible substrates and electrical cables.

An optical fiber may be used instead of the flexible substrate 24 in order to reduce noise emission and the effect of external noise. However, an optical fiber has an admissible minimum radius of curvature, which must be greater than the radius of curvature of the hinge portion 20. This leads to a large hinge portion 20 and insufficient mechanical durability of the optical fiber at its rotating portion. Therefore, it is more preferable to use free-space optical transmission as in this example, which is free from rotating portions.

In this example, the light emitting element 26 may include a light transmitting module incorporating an LED driving circuit or the like. The light receiving element 28 may include a light receiving module incorporating a waveform shaping circuit, current amplifying circuit, or the like. These modules can be used to simplify circuitry in the operating section 10 and the display section 12, thereby further reducing the effect of external noise and emission noise.

The light emitted from the light emitting element 26 can be in the infrared region, but is not limited thereto. For example, a preferable wavelength range is from 400 to 1000 nm. When the light receiving element 28 is an integrated circuit incorporating an amplifier circuit and a silicon photodiode, a range of 780 to 1000 nm is more preferable, which is in the vicinity of the sensitivity peak of the silicon photodiode.

### SECOND EXAMPLE

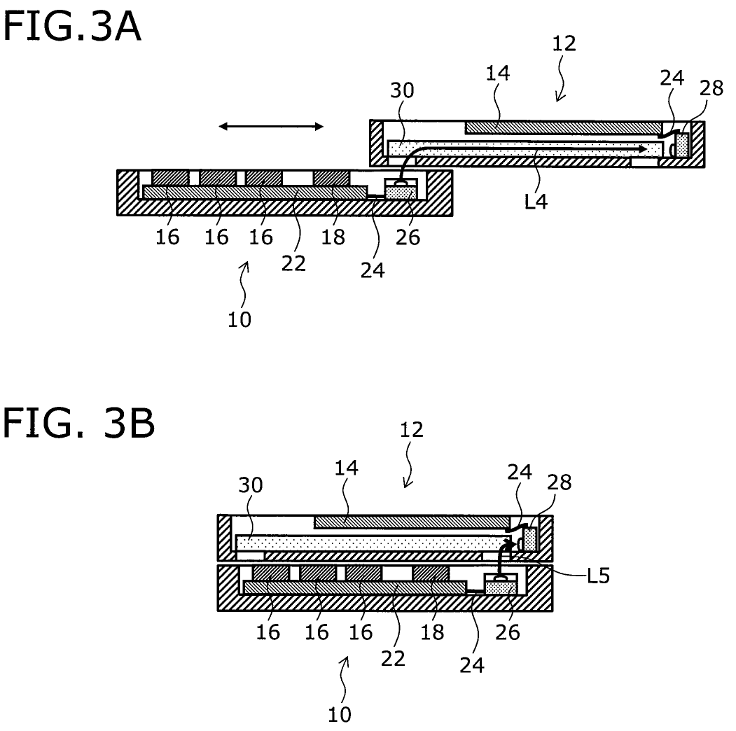

FIG. 3A is a cross section of a sliding mobile phone in its open state in the second example, and FIG. 3B is a cross section in its closed state. In these figures and the following figures, components similar to those in FIG. 1 are marked with like reference numerals and not described in detail. This example has a structure in which the display section 12 is slid back and forth relative to the operating section 10.

In this example, a signal from the control substrate 22 placed in the operating section 10 is transmitted via the connecting line 24 to the light emitting element 26 placed on the bottom of the housing of the operating section 10. The light emitted generally perpendicularly from the bottom of the housing propagates (L4) in a generally horizontal direction in the molded transparent resin portion 30 placed along the bottom of the housing of the display section 12. Here, while the cross section of the molded transparent resin portion 30 may be rectangular, a circular or elliptical shape is more preferable in view of consistency with luminous intensity distribution characteristics of the light emitting element. In the open state illustrated in FIG. 3A, the light L4 is directed to the light receiving element 28 as indicated by the arrow while being subjected to reflection or transmission at the interface with air.

In the closed state illustrated in FIG. 3B, the light L5 from the light emitting element 26 is incident on the vicinity of the tip of the molded transparent resin portion 30 and then spreads to the light receiving element 28, where it is incident thereon in the direction indicated by the arrow. In this case again, the optical path differs between the open state and the closed state. However, mechanical wear or the like will not occur as with the first example because there are no movable portions such as flexible substrates.

### THIRD EXAMPLE

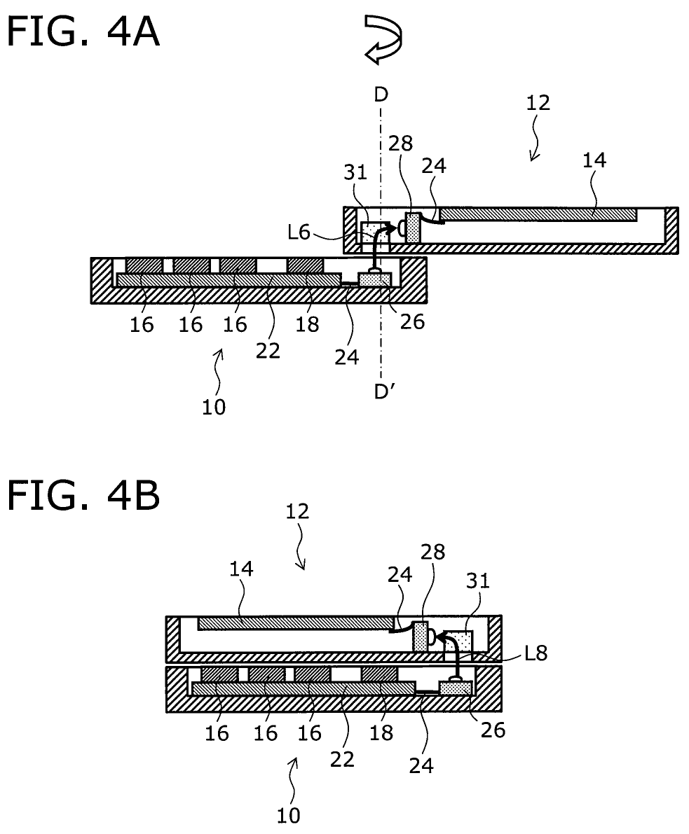

FIG. 4A is a cross section showing a rotating mobile phone in its open state in the third example, and FIG. 4B is a cross section in its closed state.

In this example, slide rotation around DD′ axis allows for an open state illustrated in FIG. 4A, or a closed state illustrated in FIG. 4B in which the operating section 10 and the display section 12 are superposed on each other. The light from the light emitting element 26 placed in the operating section 10 is incident on a molded annular transparent resin (optical guide) 31 and then spreads and propagates to the light receiving element 28, where it is incident thereon.

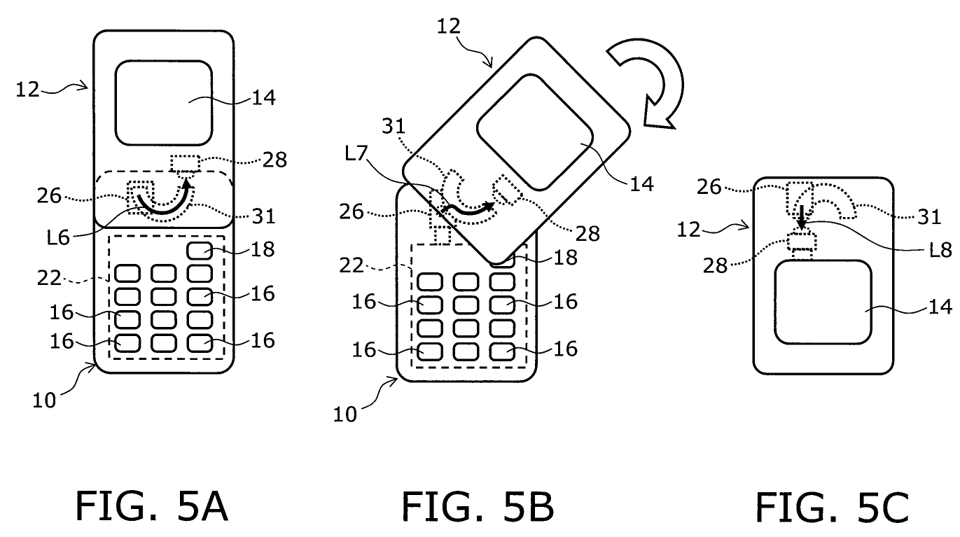

FIG. 5A is a plan view of the mobile phone in the open state illustrated in FIG. 4A, FIG. 5B is a plan view showing one position in process of slide rotation, and FIG. 5C is a plan view of the mobile phone in the closed state.

In the open state, the light L6 from the light emitting element 26 spreads and propagates in the annular transparent resin portion 31 as illustrated in FIGS. 4A and 5A, and is emitted outside. Part of the emitted light is incident on the light receiving element 28, and then converted into an electrical signal, which causes the liquid crystal display 14 to display desired data.

In process of slide rotation illustrated in FIG. 5B as well, the light L7 from the light emitting element 26 is transmitted to the light receiving element 28 via the annular transparent resin 31 as indicated by the arrow. Therefore, correct data can be displayed even at a position in process of slide rotation.

In the closed state, the light L8 from the light emitting element 26 spreads and propagates in the annular transparent resin 31 as illustrated in FIGS. 4B and 5C, and is emitted outside. Part of the emitted light is incident on the light receiving element 28, and then converted into an electrical signal, which causes the liquid crystal display 14 to display desired data. In the third example as well, the optical path L6 in the open state is different from the optical path L8 in the closed state. Furthermore, there is no mechanical wear of flexible substrates due to slide rotation. Moreover, data can be transmitted with reduced effect of external noise thereon, irrespective of the relative spatial position between the operating section 10 and the display section 12.

### FOURTH EXAMPLE

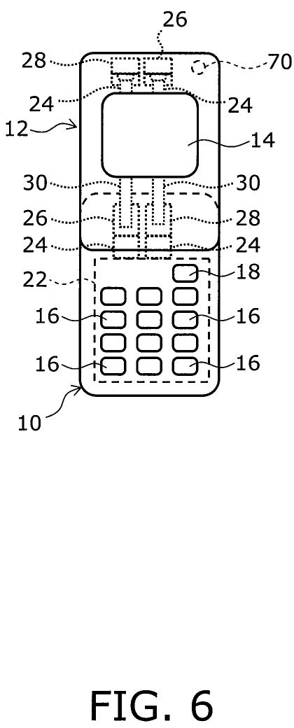

FIG. 6 is a plan view showing a mobile phone in the fourth example. In this example, which is in a sliding design similar to the second example, an independent optical transmission path is arranged between the operating section 10 and the display section 12. More specifically, in addition to the first optical transmission path composed of the light emitting element 26 placed in the operating section 10, the molded transparent resin portion 30, and the light receiving element 28 placed in the display section 12, a second optical transmission path composed of a light emitting element 26 placed in the display section 12, a molded transparent resin portion 30, and a light receiving element 28 placed in the operating section 10 is provided generally in parallel.

Data can be transmitted also from the display section 12 to the operating section 10. Data transmitted from the display section 12 include an image from the camera section 70 provided in the display section 12 and data stored in a semiconductor memory section provided in the display section. This example allows for bidirectional data transmission.

### FIFTH EXAMPLE

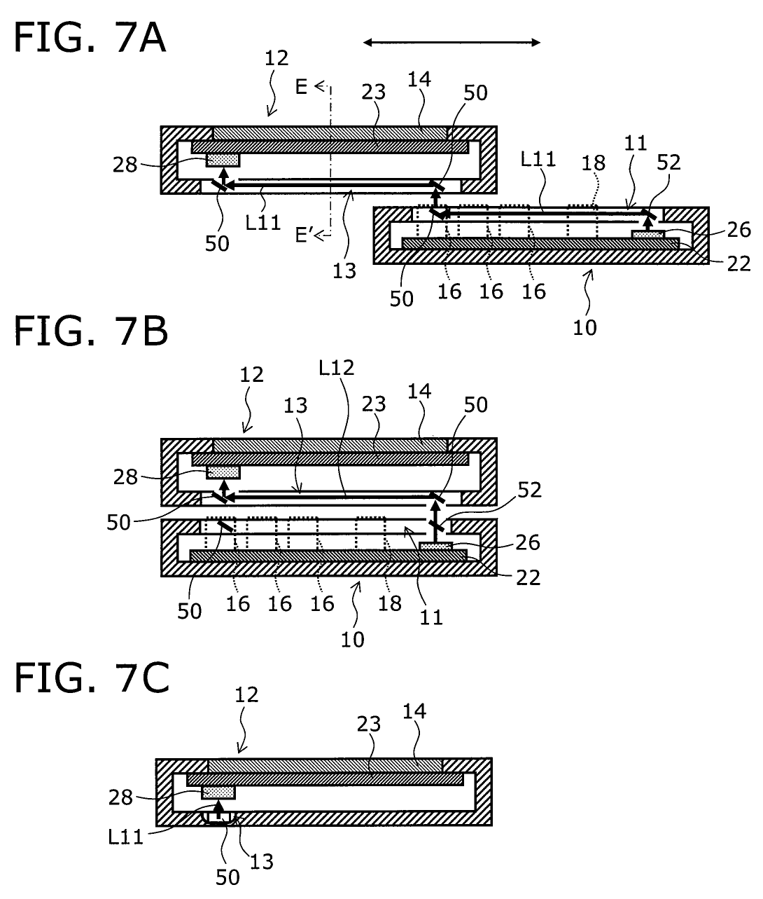

FIG. 7A is a cross section in the open state, and FIG. 7B is a cross section in the closed state. In this example, the light emitting element 26 is provided on the control substrate 22 placed in the housing of the operating section 10.

First, in the open state illustrated in FIG. 7A, an in-housing space 11 is provided above the operating section 10. The light Log emitted upward from the light emitting element 26 is reflected from a half mirror 52 and propagates along the in-housing space 11. The light L11 reflected from a reflecting plate 50 placed at the other end of the in-housing space 11 is reflected from a reflecting plate 50 placed in the display section 12 and propagates along an in-housing space 13 in the display section 12. The light L11 reflected upward by a reflecting plate 50 placed at the other end of the in-housing space 13 is incident on the light receiving element 28 placed on a display section substrate 23. In this way, by electro-optically converting data from the operating section 10, the data can be transmitted to the display section 12 with reduced effect of external noise and reduced noise emission. The data, after opto-electrical conversion, is displayed on the liquid crystal display 14.

In the closed state where the display section 12 is slid as illustrated in FIG. 7B, the light L12 emitted upward from the light emitting element 26 is transmitted through the half mirror 52, then reflected by the reflecting plate 50 placed in the display section 12, and propagates along the in-housing space 13. The light L12 reflected upward by the reflecting plate 50 placed at the other end of the in-housing space 13 is incident on the light receiving element 28.

FIG. 7C is a cross section along dot-dashed line EE′ in FIG. 7A. The light L11 transmitted from the operating section 10 travels along the in-housing space 13, is bent upward by the reflecting plate 50, and reaches the light receiving element 28. In this case, the in-housing space 13 can be shaped as a U-groove as illustrated in FIG. 7C to prevent parts placed on the display section substrate 23 from obstructing the optical path. Alternatively, a tunnel-like space can be used instead of the U-groove.

In this case, the light emitting element 26 can be an LED or VCSEL. A VCSEL is more preferable for ensuring a bandwidth as wide as 400 MHz and transmitting light in the in-housing spaces 11 and 13 without divergence under low-current operation.

In this way, in the closed state as well, by electro-optically converting a signal from the operating section 10, data can be transmitted to the display section 12. The data, after opto-electrical conversion, is displayed on the liquid crystal display 14. In this example as well, the optical path for the light L11 in the open state can be varied from that for the light L12 in the closed state to eliminate flexible substrates or the like.

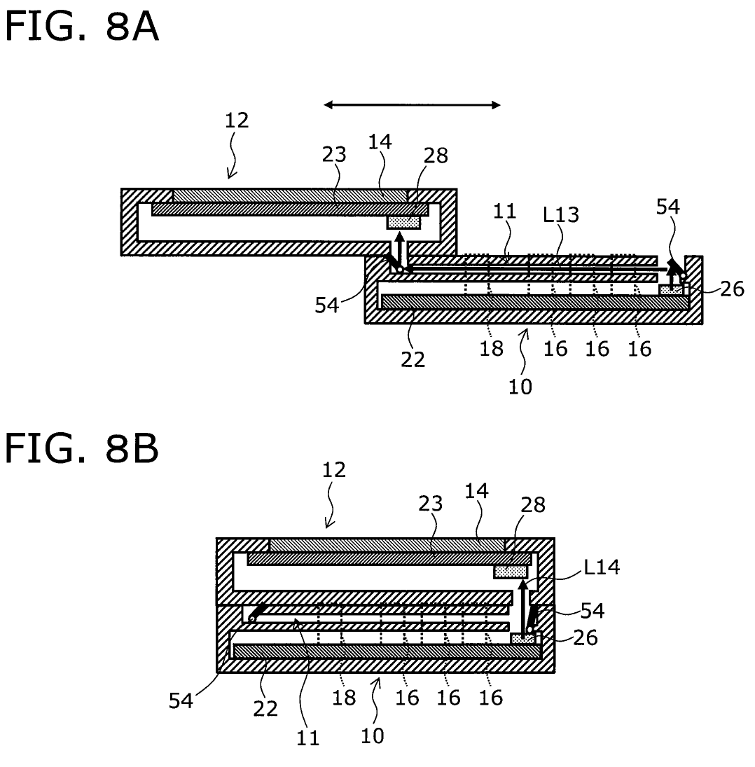

Next, a variation of the fifth example is described. FIG. 8A is a cross section in the open state in the variation, and FIG. 8B is a cross section in the closed state. In this variation, movable reflecting plates 54 are provided instead of the reflecting plates 50 and half mirror 52. In the open state as illustrated in FIG. 8A, the light L13 from the light emitting element 26 is bent by the movable reflecting plate 54 and propagates along the in-housing space 11 of the operating section 10. The light L13 is bent by the movable reflecting plate 54 or reflecting plate at the other end of the in-housing space 11 and incident on the light receiving element 28.

In the closed state illustrated in FIG. 8B, slide motion of the display section 12 causes the movable reflecting plate 54 to change its orientation so that the light L14 from the light emitting element 26 travels in a straight line. As a result, the light L15 is incident on the light receiving element 28. In this case again, the optical path differs between the open state and the closed state.

### SIXTH EXAMPLE

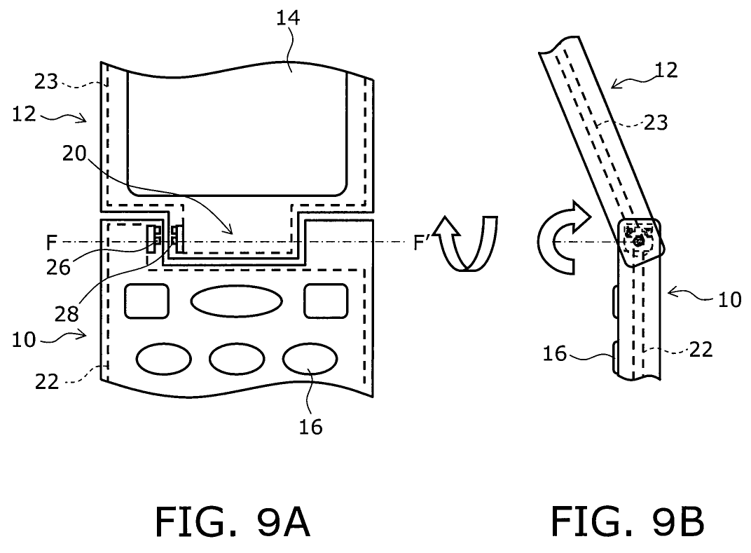

FIG. 9A is a view showing the vicinity of a hinge portion 20, and FIG. 9B is a partial cross section thereof. In this example, the light emitting element 26 and the light receiving element 28 are facing to each other at one end of the hinge portion 20. An electrical signal from the control substrate 22 in the operating section 10 is converted into an optical signal, which is transmitted in free space. The light receiving element performs opto-electrical conversion, and the resulting data is transmitted via the display section substrate 23 to the liquid crystal display 14.

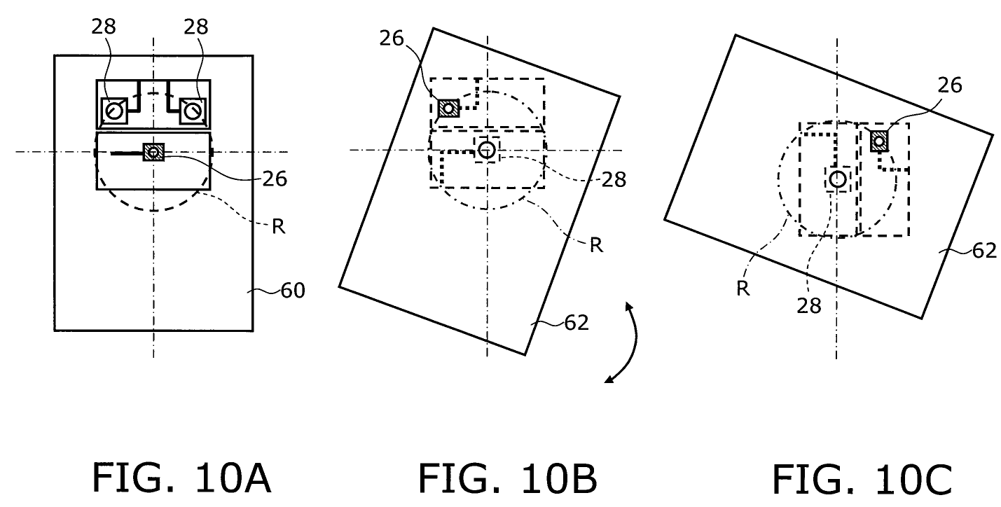

FIG. 10 is a cross section for illustrating optical transmission in the open and closed states in accordance with rotation of the hinge portion 20. FIG. 10A shows an operating section optical element mounting substrate 60, and is a view as viewed from the right side of the rotation axis FF′ in FIG. 9A.

The operating section optical element mounting substrate 60 illustrated in FIG. 10A is electrically connected to the control substrate 22 in the operating section 10, where the light emitting element 26 performs electro-optical conversion. Here, the emission center of the light emitting element 26 substantially coincides with the rotation axis FF′ of the hinge portion 20. Two light receiving elements 28 are placed substantially on an identical circle R around the rotation axis FF′ of the hinge portion 20, and thereby can receive an optical signal from the display section 12.

FIG. 10B shows a display section optical element mounting substrate 62 in the closed state in which it is facing to the operating section optical element mounting substrate 60, and is a view as viewed from the right side of the rotation axis FF′ in FIG. 9. On the display section optical element mounting substrate 62, a light receiving element 28 receiving light from the light emitting element 26 of the operating section 10 is placed in a plane generally perpendicular to the rotation axis FF′ of the hinge portion 20. The light receiving element 28 receives an optical signal from the operating section 10 and converts it into an electrical signal. A light emitting element 26 is placed around the rotation axis FF′ of the hinge portion 20. The light emitting element 26 electro-optically converts the signal from the display section 12 and then transmits the resulting optical signal to the left one of the two light receiving elements 28 in FIG. 10A on the operating section optical element mounting substrate 60.

FIG. 10C shows a display section optical element mounting substrate 62 in the open state. This is the state rotated from the closed state illustrated in FIG. 10B, and the position of the light emitting element 26 is different from that in the closed state. Because the position facing to the operating section optical element mounting substrate 60 is rotated, the right one of the light receiving elements 28 in FIG. 10A is now responsible for reception in contrast to the closed state. In this way, optical transmission and reception can be performed both at the open and closed positions by placing two or more light receiving elements 28 on an identical circle R, each corresponding to the rotation angle. Here, the optical path for transmission from the display section 12 differs between the open state (FIG. 10C) and the closed state (FIG. 10B). Note that what is placed in the vicinity of the rotation axis on the hinge portion 20 of the operating section 10 is not limited to the light emitting element 26, where the light receiving element 28 can be placed alternatively. In this case, the light emitting element 26 should all be interchanged with the light receiving elements 28 in the example. In this way, this example also allows for bidirectional optical transmission between the operating section 10 and the display section 12. By applying a driving voltage to both the two light receiving elements 28, either one of the light receiving elements can detect an optical signal.

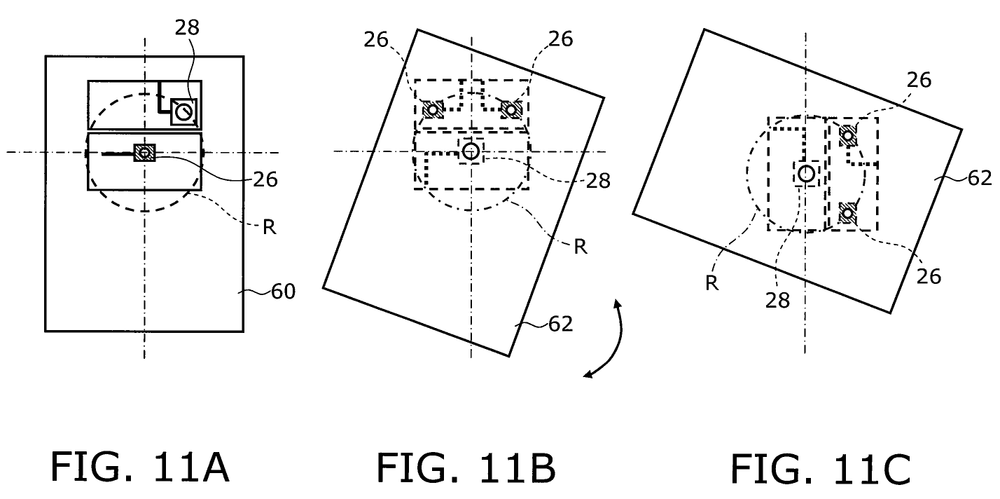

FIG. 11 is a view showing a first variation of the sixth example. In the sixth example described above, two light receiving elements 28 are placed on the identical circle R around the rotation axis FF′ of the operating section optical element mounting substrate 60. In this variation, however, two light emitting elements 26 are placed on the identical circle R around the rotation axis FF′ of the display section optical element mounting substrate 62.

FIG. 11A shows the operating section optical element mounting substrate 60, where a light emitting element 26 is placed in the vicinity of the rotation axis FF′, and one light receiving element 28 is placed on the circle R. In contrast, on the display section optical element mounting substrate 62, a light receiving element 28 is placed in the vicinity of the rotation axis FF′, and two light emitting elements 26 are placed on the identical circle R around the rotation axis FF′.

FIG. 11B shows the closed state, where an optical signal from the display section 12 is transmitted from the right one of the light emitting elements 26 in FIG. 11B to the light receiving element 28 in FIG. 11A. FIG. 11C shows the open state, where an optical signal from the display section 12 is transmitted from the upper one of the light emitting elements 26 in FIG. 11C to the light receiving element 28 in FIG. 11A. In the first variation as well, what is placed in the vicinity of the rotation axis on the hinge portion 20 of the operating section 10 is not limited to the light emitting element, where the light receiving element can be placed alternatively. In this case, the light emitting element 26 should all be interchanged with the light receiving elements in the example. The light emitting element 26 is more suitable for downsizing because it is typically smaller in area than the light receiving element 28.

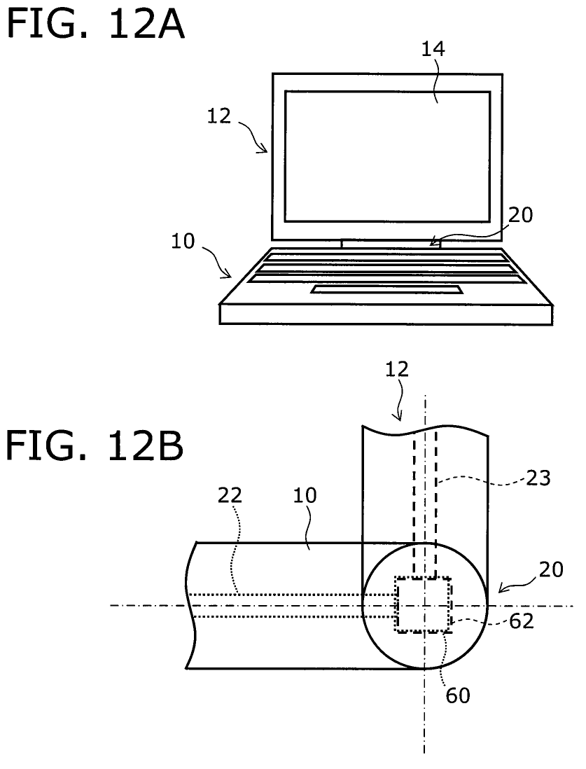

FIG. 12 shows a second variation of the sixth example, where FIG. 12A is a view of a personal computer, and FIG. 12B is a side view in the vicinity of the hinge portion 20. When the angle in the open state is different from that for the folding phone, the light receiving elements 28 can be placed accordingly to achieve similar advantageous effects.

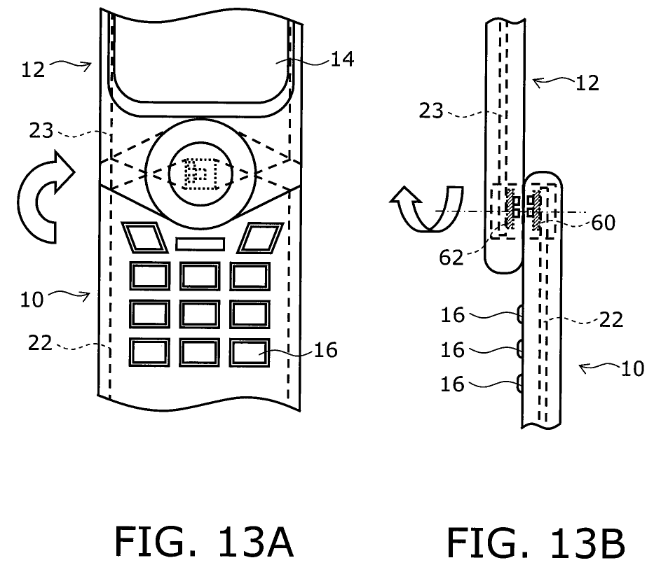

FIG. 13 shows a rotating phone in a third variation of the sixth example. FIG. 13A is a partial plan view thereof, and FIG. 13B is a partial cross section thereof. Advantageous functions and effects similar to those in the sixth example are achieved except for horizontal arrangement of the operating section optical element mounting substrate 60 and the display section optical element mounting substrate 62.

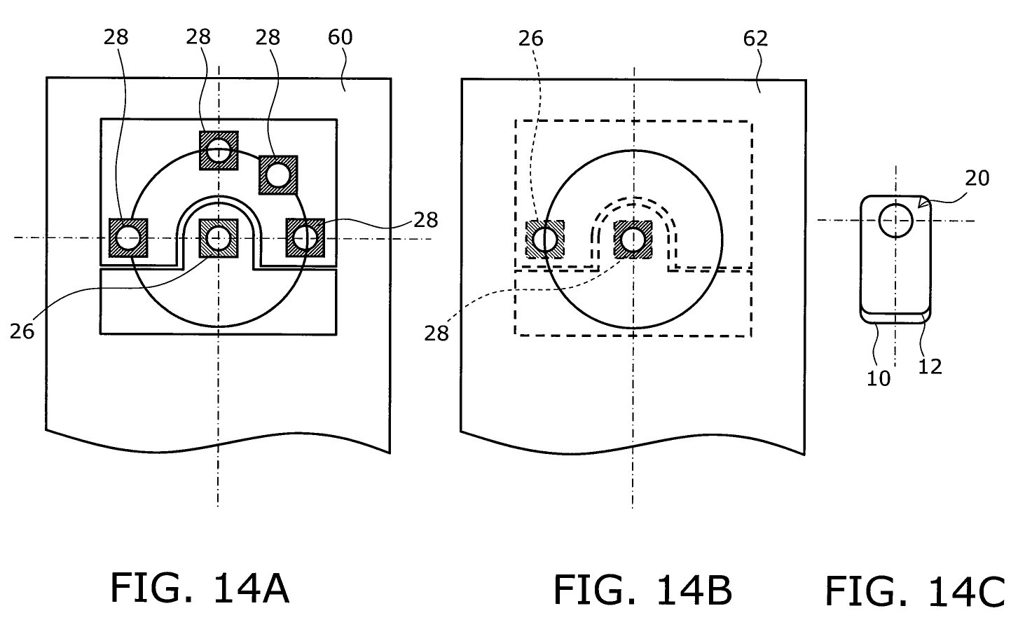

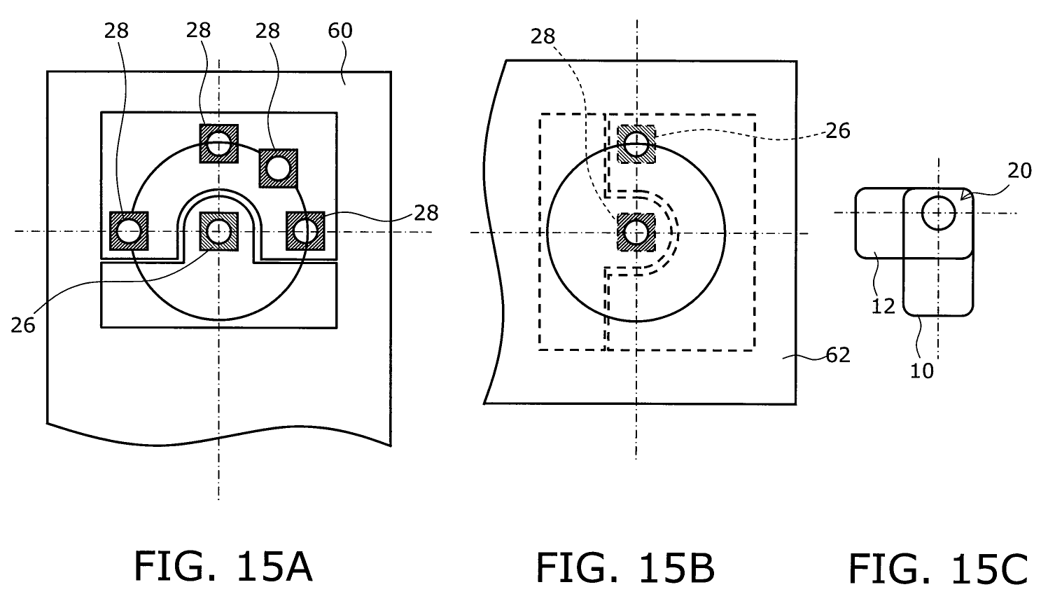

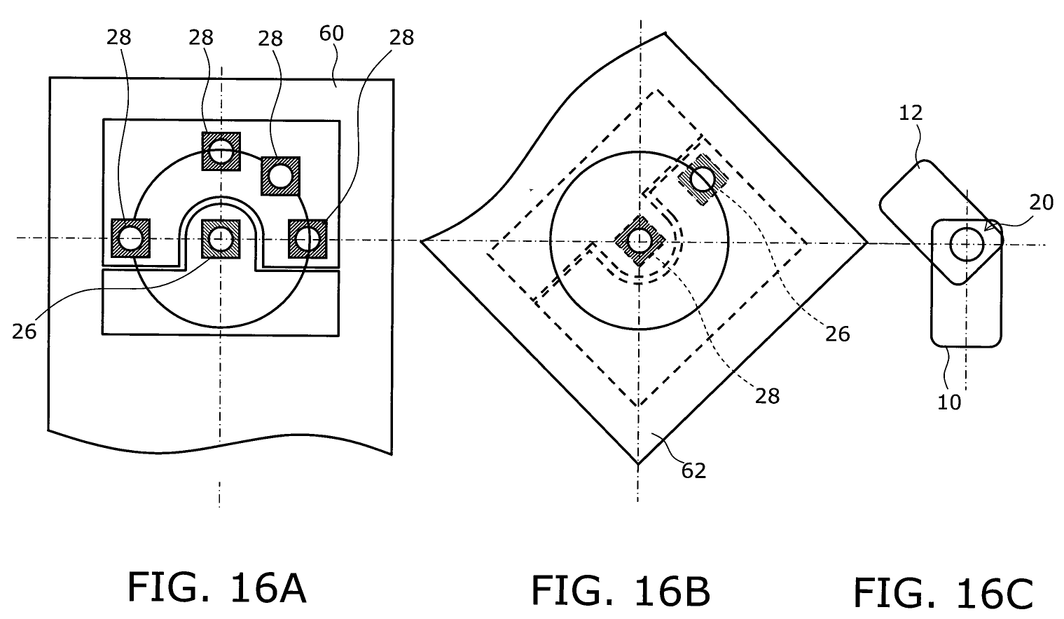

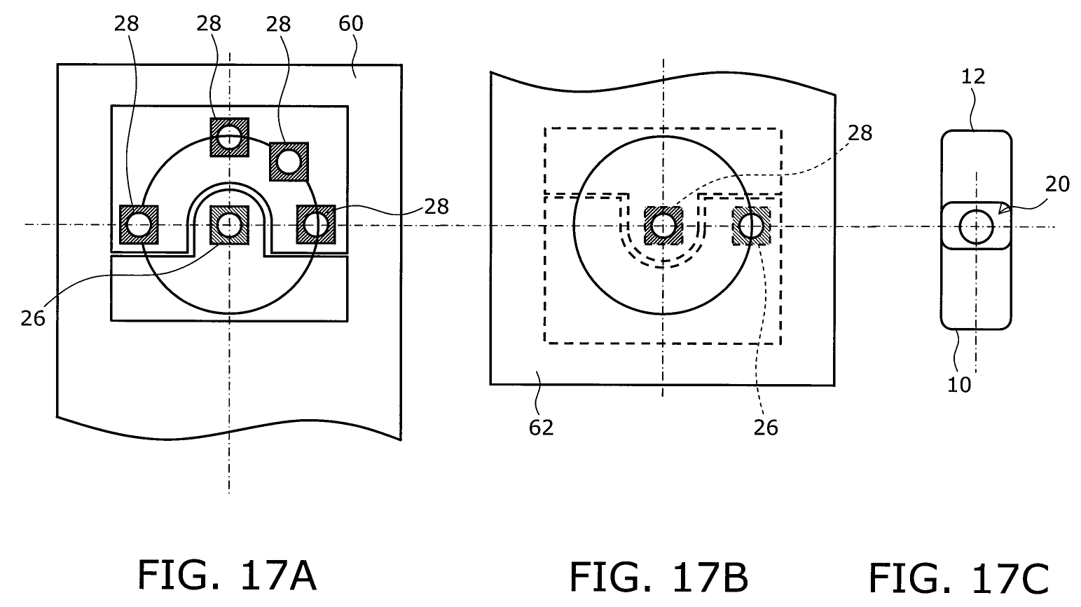

FIGS. 14 to 17 show a portable electronic device in a fourth variation of the sixth example. FIGS. 14A, 15A, 16A, and 17A are views of the operating section optical element mounting substrate 60, FIGS. 14B, 15B, 16B, and 17B show the display section optical element mounting substrate 62, and FIGS. 14C, 15C, 16C, and 17C are side views in the vicinity of the hinge portion 20. FIG. 14 shows the closed state, FIGS. 15 and 16 show intermediate positions between the closed and open states, and FIG. 17 shows the open state. Even if the angle in the open state reaches 180 degrees, bidirectional optical transmission can be achieved in accordance with the rotation angle by placing, for example, four light receiving elements 28 on an identical circle. On the rotation axis, the light emitting element 26 and the light receiving element 28 are provided. This implementation is not limited to the slide rotating portable device, but may be applied to a folding design as shown in FIGS. 9A and 9B, for example. Further, instead of providing a plurality of light receiving elements, a plurality of light emitting elements may be provided. In the sixth example described above as well, the optical path between the light emitting element 26 and the light receiving element 28 can be changed from the closed state to the open state and vice versa to transmit an optical signal in both directions.

As described above, in the first to sixth examples, a signal is electro-optically converted in the operating section 10. The resulting optical signal from the light emitting element 26 reaches the display section 12 via free-space transmission without the intermediary of movable portions such as flexible substrates. The optical signal is opto-electrically converted by the light receiving element 28 in the display section 12, and the resulting data is displayed on a liquid crystal display or the like.

Here, when the device is carried about, it requires to be downsized by changing the relative position of the operating section 10 and the display section 12 by folding, sliding, or rotation. In both the open and closed states by such folding, sliding, or rotation, data transmission is required between the operating section 10 and the display section 12. To this end, conventionally, a flexible substrate or the like has been used. However, the flexible substrate or the like is mechanically worn as the number of opening/closing motions increases. Furthermore, as the communication system becomes more sophisticated, the amount of data transmission tends to increase, which requires increasing the number of signal lines. The increase of signal lines hinders downsizing.

In the first to sixth examples, different optical paths can be formed in the free-space optical transmission path in the open and closed states to allow for data transmission without movable portions such as flexible substrates, electrical cables, and optical fibers. Furthermore, because of great flexibility in placing the light emitting element and the light receiving element, the invention is applicable to any of the folding, rotating, and sliding designs. As a result, mechanical durability is improved, and the increased amount of data transmission can be addressed.

Moreover, use of optical transmission allows for reducing the effect of external noise, which results in improved bit error rate and reduced malfunctions. Reduction of noise emission allows for reducing EMI (Electro-Magnetic Interference) to other electronics.

Embodiments of the invention have been described with reference to the drawings. However, the invention is not limited to thereto. Any size, shape, and material of various components including the light emitting element, light receiving element, reflecting plate, half mirror, and molded transparent resin that are variously adapted by those skilled in the art are also encompassed within the scope of the invention as long as they meet the requirements of the invention.

1. A portable electronic device comprising:
an operating section;
a display section configured to perform display based on information transmitted from the operating section;
a light emitting element provided in one of the operating section and the display section; and
a light receiving element provided in other of the operating section and the display section,
the operating section and the display section being enabled to be in an open state and a closed state by changing a superposition condition thereof, and
an optical path interconnecting the light emitting element and the light receiving element in the open state being different from an optical path interconnecting the light emitting element and the light receiving element in the closed state.

2. A portable electronic device of claim 1, further comprising a hinge portion which connects the operating section and the display section in foldable manner,
wherein one of the operating section and the display section includes a first light emitting element which emits light in a direction substantially parallel to a rotation axis of the hinge portion, and a plurality of first light receiving elements provided on a circle centered on the rotation axis,
other of the operating section and the display section includes a second light receiving element facing to the first light emitting element in one of the open state and the closed state, and a second light emitting element provided on the circle centered on the rotation axis, and
light emitted from the second light emitting element is incident on one of the plurality of first light receiving elements in both of the open state and in the closed state.

3. A portable electronic device of claim 2, wherein the first light emitting element and the second light receiving element are provided on the rotation axis.

4. A portable electronic device of claim 1, wherein
the superposition condition of the operating section and the display section is changed by relative sliding rotation around a common rotation axis,
one of the operating section and the display section includes a first light emitting element which emits light in a direction substantially parallel to the rotation axis and a plurality of first light receiving elements provided on a circle centered on the rotation axis,
other of the operating section and the display section includes a second light receiving element facing to the first light emitting element in the open state and the closed state, and a second light emitting element provided on the circle centered on the rotation axis, and
light emitted from the second light emitting element is incident on one of the plurality of first light receiving elements in both of the open state and in the closed state.

5. A portable electronic device of claim 4, wherein the first light emitting element and the second light receiving element are provided on the rotation axis.

6. A portable electronic device of claim 1, further comprising:
a hinge portion which connects the operating section and the display section in foldable manner, wherein
one of the operating section and the display section includes a first light emitting element which emits light in a direction substantially parallel to the rotation axis and a first light receiving elements provided on a circle centered on the rotation axis,
other of the operating section and the display section includes a second light receiving element facing to the first light emitting element in the open state and the closed state and a plurality of second light emitting elements provided on the circle centered on the rotation axis, and
light emitted from one of the plurality of second light emitting elements is incident on the first light receiving element in both of the open state and the closed state.

7. A portable electronic device of claim 6, wherein the first light emitting element and the second light receiving element are provided on the rotation axis.

8. A portable electronic device of claim 1, wherein
the superposition condition of the operating section and the display section is changed by relative sliding rotation around a common rotation axis,
one of the operating section and the display section includes a first light emitting element which emits light in a direction substantially parallel to the rotation axis and a first light receiving element provided on a circle centered on the rotation axis,
the other of the operating section and the display section includes a second light receiving element facing to the first light emitting element in the open state and the closed state and a plurality of second light emitting elements provided on the circle centered on the rotation axis, and
light emitted from one of the plurality of second light emitting elements is incident on the first light receiving element in both of the open state and the closed state.

9. A portable electronic device of claim 8, wherein the first light emitting element and the second light receiving element are provided on the rotation axis.

10. A portable electronic device comprising:
an operating section;
a display section configured to perform display based on information transmitted from the operating section;
a first light emitting element provided in one of the operating section and the display section; and
a first light receiving element provided in other of the operating section and the display section,
the operating section and the display section being enabled to be in an open state and a closed state by changing a superposition condition thereof,
a first optical path interconnecting the first light emitting element and the first light receiving element in the open state being different from a second optical path interconnecting the first light emitting element and the first light receiving element in the closed state, and
a first optical guide being provided in at least a part of the first optical path and in at least a part of the second optical path.

11. A portable electronic device of claim 10, further comprising a hinge portion which connects the operating section and the display section in foldable manner, wherein
the first optical guide is provided in the hinge portion and fixed to the operating section,
light emitted from the first light emitting element propagates through the first optical guide is then emitted from the first optical guide at a first position, and is incident on the first light receiving element in the open state, and
light emitted from the first light emitting element propagates through the first optical guide is then emitted from the first optical guide at a second position which is different from the first position, and is incident on the first light receiving element in the closed state.

12. A portable electronic device of claim 10, wherein
the superposition condition of the operating section and the display section is changed by relative sliding motion,
the first optical guide is provided in one of the operating section and the display section,
the first optical guide extends in a direction of the relative sliding motion,
light emitted from the first light emitting element propagates through the first optical guide is then emitted from the first optical guide at a first position, and is incident on the first light receiving element in the open state, and
light emitted from the first light emitting element propagates through the first optical guide is then emitted from the first optical guide at a second position which is different from the first position, and is incident on the first light receiving element in the closed state.

13. A portable electronic device of claim 10, wherein
the superposition condition of the operating section and the display section is changed by relative sliding rotation around a common rotation axis,
the first optical guide is provided in one of the operating section and the display section,
the first optical guide includes at least a part of an annular ring centered on the rotation axis,
light emitted from the first light emitting element propagates through the first optical guide is then emitted from the first optical guide at a first position, and is incident on the first light receiving element in the open state, and
light emitted from the first light emitting element propagates through the first optical guide is then emitted from the first optical guide at a second position which is different from the first position, and is incident on the first light receiving element in the closed state.

14. A portable electronic device of claim 10, wherein
the operating section includes the first light emitting element,
the operating section further includes a second light receiving element,
the display section further includes a second light emitting element,
light emitted from the first light emitting element is incident on the first light receiving element through the first optical guide, and
light emitted from the second light emitting element is incident on the second light receiving element through a second optical guide.

15. A portable electronic device of claim 14, wherein the superposition condition of the operating section and the display section is changed by relative sliding motion.

16. A portable electronic device of claim 14, further comprising a hinge portion which connects the operating section and the display section in foldable manner, wherein the first and the second optical guides are provided in the hinge portion and fixed to the operating section.

17. A portable electronic device comprising:
an operating section;
a display section configured to perform display based on information transmitted from the operating section;
a first light emitting element provided in one of the operating section and the display section; and
a first light receiving element provided in other of the operating section and the display section,
the operating section and the display section being enabled to be in an open state and a closed state by changing a superposition condition thereof,
at least one of the operating section and the display section being provided with a space for propagating light emitted from the light emitting element, and
different optical paths being formed in the open state and in the closed state by a reflecting plate provided in at least one of the operating section and the display section.

18. A portable electronic device of claim 17, wherein the reflecting plate include a half mirror.

19. A portable electronic device of claim 17, wherein the reflecting plate include a movable reflecting plate which changes a direction of reflection in the open state and in the closed state.

20. A portable electronic device of claim 17, wherein the light emitting element emits the light in a direction substantially perpendicular to a direction of propagation of the light in the space.
